(19) United States
(12) Patent Application Publication
(10) Pub. No.: US 2025/0031478 A1
(43) Pub. Date: Jan. 23, 2025

(54) PASSIVATION METHOD

(71) Applicant: COMMISSARIAT À L'ENERGIE ATOMIQUE ET AUX ENERGIES ALTERNATIVES, Paris (FR)

(72) Inventors: Baptiste MARTEAU, Grenoble Cedex 09 (FR); Thibaut DESRUES, Grenoble Cedex 09 (FR); Bernadette GRANGE, Grenoble Cedex 09 (FR)

(73) Assignee: COMMISSARIAT À L'ENERGIE ATOMIQUE ET AUX ENERGIES ALTERNATIVES, Paris (FR)

(21) Appl. No.: 18/713,875

(22) PCT Filed: Nov. 22, 2022
(86) PCT No.: PCT/EP2022/082868

§ 371 Date: May 28, 2024

(30) Foreign Application Priority Data
Nov. 29, 2021 (FR) FR2112689

(51) Int. Cl. H01L 31/18

(52) U.S. Cl. CPC H01L 31/1868; H01L 31/182; H01L 31/1864

(57) ABSTRACT

A passivation process, including the following successive steps: a) providing a structure including a crystalline silicon-based substrate having opposite first and second surfaces; first and second oxide films; b) applying ultraviolet radiation to the structure, under an ozone atmosphere, in such a way that the first oxide film has: a thickness strictly greater than the thickness of the second oxide film, and/or a composition closer to the stoichiometric compound; c) forming first and second polysilicon layers on the first and second oxide films, respectively, these first and second polysilicon layers comprising phosphorus atoms and boron atoms, respectively; d) applying a heat treatment at a temperature greater than or equal to the electrical activation temperature of the boron atoms so as to electrically activate the phosphorus atoms and the boron atoms concomitantly.

### TECHNICAL FIELD

The invention relates to the technical field of passivation of surfaces of a crystalline silicon-based substrate.

The invention is in particular applicable to the manufacture of photovoltaic cells, and in particular silicon-based photovoltaic cells. Surface passivation is a major challenge in the photovoltaic sector. It makes it possible to limit recombination of minority and majority carriers, and therefore to increase the number of carriers collected, this resulting in a significant improvement in efficiency.

### PRIOR ART

A known prior-art photovoltaic cell comprises:
a crystalline silicon-based substrate having opposite first and second surfaces;
first and second oxide films formed on the first and second surfaces of the substrate, respectively;
first and second polysilicon layers formed on the first and second oxide films, respectively, these first and second polysilicon layers comprising phosphorus atoms and boron atoms, respectively.

The stack consisting of a “polysilicon layer on an oxide film” allows a good passivation of the surfaces of the substrate to be obtained. Specifically, the oxide films allow dangling bonds on the surfaces of the substrate to be filled, which makes it possible to obtain a chemical passivation of the surfaces. The oxide films also act as a barrier against diffusion of phosphorus atoms and boron atoms from the corresponding polysilicon layer into the substrate. The oxide films therefore make it possible to preserve, in the polysilicon layers, a level of doping with phosphorus and boron atoms sufficient to ensure a good quality electrical contact is obtained.

However, passivation of the surfaces of the substrate requires electrical activation of the phosphorus atoms and boron atoms. However, the optimum electrical activation temperature of the boron atoms is strictly greater than the electrical activation temperature of the phosphorus atoms. By way of illustrative example, the optimum electrical activation temperature of the boron atoms may be of the order of 950° C., and the electrical activation temperature of the phosphorus atoms may be of the order of 875° C. when the polysilicon layers have a thickness of 15 nm, the oxide films have a thickness of 1.5 nm and the boron/phosphorus atoms are implanted by plasma-immersion ion implantation. Application of a heat treatment at a temperature greater than or equal to the electrical activation temperature of the boron atoms may therefore lead to excessive diffusion of phosphorus atoms out of the polysilicon layer, potentially leading to substantial degradation of the performance of the photovoltaic cell.

One solution could consist in applying two successive heat treatments to electrically activate the phosphorus atoms and boron atoms separately in an optimum manner. This solution is unsatisfactory from an industrial point of view because it results in a significant increase in operating time.

It is therefore sought, by those skilled in the art, to apply a single heat treatment to electrically activate the boron atoms and the phosphorus atoms simultaneously, while avoiding excessive diffusion of phosphorus atoms degrading the performance of the photovoltaic cell.

### SUMMARY OF THE INVENTION

The invention aims to remedy all or some of the aforementioned drawbacks. To this end, one subject of the invention is a passivation process, comprising the following successive steps:
a) providing a structure comprising:
   a crystalline silicon-based substrate having opposite first and second surfaces;
   first and second oxide films formed on the first and second surfaces of the substrate, respectively;
b) applying ultraviolet radiation to the structure, under an ozone atmosphere, in such a way that the first oxide film has:
   a thickness strictly greater than the thickness of the second oxide film, and/or
   a composition closer to the stoichiometric compound;
c) forming first and second polysilicon layers on the first and second oxide films, respectively, these first and second polysilicon layers comprising phosphorus atoms and boron atoms, respectively, the phosphorus atoms and boron atoms having first and second electrical activation temperatures, respectively, the second electrical activation temperature being strictly greater than the first electrical activation temperature;
d) applying a heat treatment to the assembly comprising the structure and the first and second polysilicon layers, the heat treatment being applied at a temperature greater than or equal to the second electrical activation temperature so as to electrically activate the phosphorus atoms and the boron atoms concomitantly.

Thus, such a process according to the invention makes it possible, by virtue of step b), to electrically activate the phosphorus atoms and the boron atoms simultaneously in step d), while preventing excessive diffusion of the phosphorus atoms out of the first polysilicon layer in step d). Specifically, the UV-ozone treatment applied in step b) allows, by increasing the thickness and/or modifying the composition of the first oxide film (closer to a stoichiometric composition than the composition of step a)), blockage of the diffusion of phosphorus atoms from the first polysilicon layer into the substrate in step d) to be improved. Specifically, increasing the thickness and/or modifying the composition of the first oxide film (by virtue of a composition closer to the stoichiometric compound, or even tending toward the stoichiometric compound) improves its quality as a barrier to diffusion of phosphorus atoms, this diffusion barrier then being able to resist a temperature greater than or equal to the electrical activation temperature of the boron atoms.

The process according to the invention may comprise one or more of the following features.

According to one feature of the invention, step a) comprises the following steps:
a₁) providing a crystalline silicon-based substrate having opposite first and second surfaces;
a₂) chemically treating the first and second surfaces of the substrate with an oxidizing agent so as to form the first and second oxide films.

One advantage thereof is that advantage is taken of a chemical treatment (for example for cleaning the first and second surfaces) to form the first and second oxide films.

According to one feature of the invention, step a) comprises the following steps:
a_{1′}) providing a crystalline silicon-based substrate having opposite first and second surfaces;
a_{2′}) heat treating the first and second surfaces of the substrate so as to form first and second films of thermal-oxide type.

One advantage thereof is that the first and second thermal oxide films may be formed in the same processing tool as that used to form the first and second polysilicon layers, the processing tool for example being configured to carry out LPCVD, LPCVD standing for low-pressure chemical vapor deposition.

According to one feature of the invention, step a) comprises the following steps:
a_{1″}) providing a crystalline silicon-based substrate having opposite first and second surfaces;
a_{2″}) chemically treating the first and second surfaces of the substrate with an oxidizing agent so as to form a first portion of the first and second oxide films;
a_{3″}) heat treating the oxidized first and second surfaces of the substrate so as to form a second portion of the first and second oxide films.

Thus, one advantage of combining a chemical treatment and a heat treatment to form the first and second oxide films is that:
(i) advantage may be taken of cleaning of the surfaces to form the first part of the oxide films,
(ii) the same processing tool may be used to form the second portion of the oxide films and the polysilicon layers, the processing tool for example being configured to carry out LPCVD, LPCVD standing for low-pressure chemical vapor deposition.

According to one feature of the invention, step a) is executed in such a way that the first and second oxide films are of tunnel-oxide type.

One advantage thereof is that a barrier to diffusion of phosphorus atoms and boron atoms is formed, while advantageously permitting an electric current to flow therethrough via a tunneling effect.

Another subject of the invention is a passivation process, comprising the following successive steps:
a′) providing a crystalline silicon-based substrate having opposite first and second surfaces;
b) applying ultraviolet radiation to the substrate, under an ozone atmosphere, so as to form first and second oxide films on the first and second surfaces of the substrate, respectively, the first oxide film having:
   a thickness strictly greater than the thickness of the second oxide film, and/or
   a composition tending toward the stoichiometric compound;
c) forming first and second polysilicon layers on the first and second oxide films, respectively, these first and second polysilicon layers comprising phosphorus atoms and boron atoms, respectively, the phosphorus atoms and boron atoms having first and second electrical activation temperatures, respectively, the second electrical activation temperature being strictly greater than the first electrical activation temperature;
d) applying a heat treatment to the assembly comprising the substrate, the first and second oxide films and the first and second polysilicon layers, the heat treatment being applied at a temperature greater than or equal to the second electrical activation temperature so as to electrically activate the phosphorus atoms and the boron atoms concomitantly.

Thus, such a process according to the invention makes it possible, by virtue of step b), to electrically activate the phosphorus atoms and the boron atoms simultaneously in step d), while preventing excessive diffusion of the phosphorus atoms out of the first polysilicon layer in step d). Specifically, the UV-ozone treatment applied in step b) makes it possible to form a first oxide film:
that is thicker than the second oxide film, and/or
that is of a composition tending toward the stoichiometric compound.

Such a UV-ozone treatment thereby improves blockage of the diffusion of phosphorus atoms from the first polysilicon layer into the substrate in step d). Specifically, the obtained thickness of the first oxide film (greater than the thickness of the second oxide film) and/or the obtained composition of the first oxide film (tending toward the stoichiometric compound) improve/improves its quality as a barrier to diffusion of phosphorus atoms, this diffusion barrier then being able to resist a temperature greater than or equal to the electrical activation temperature of the boron atoms.

According to one feature of the invention, step b) is executed in such a way that the first and second oxide films are of tunnel-oxide type.

One advantage thereof is that a barrier to diffusion of phosphorus atoms and boron atoms is formed, while advantageously permitting an electric current to flow therethrough via a tunneling effect.

According to one feature of the invention, the ultraviolet radiation applied in step b), under the ozone atmosphere, is configured so that the thickness and/or composition of the first oxide film at the end of step b) limit/limits diffusion of phosphorus atoms into the substrate in step d).

One advantage thereof is that the performance of the photovoltaic cell is improved.

According to one feature of the invention, the ultraviolet radiation is applied in step b), under the ozone atmosphere, with a power density per unit area comprised between 28 W/cm² and 32 W/cm².

According to one feature of the invention, the ultraviolet radiation is applied in step b), under the ozone atmosphere, with a wavelength in the absorption band of ozone, preferably comprised between 250 nm and 255 nm.

One advantage thereof is that the effectiveness of the UV-ozone treatment is improved.

According to one feature of the invention, the temperature at which the heat treatment is applied in step d) is comprised between 950° C. and 1050° C.

One advantage thereof is that it is possible to electrically activate the phosphorus atoms and the boron atoms simultaneously.

According to one feature of the invention, step c) comprises the following steps:
c₁) forming the first and second polysilicon layers on the first and second oxide films, respectively;
c₂) implanting phosphorus atoms and boron atoms in the first and second polysilicon layers, respectively, preferably by plasma-immersion ion implantation.

According to one feature of the invention, step c) is executed in such a way that the phosphorus atoms and boron atoms have a density greater than 10²⁰ at./cm³ at the end of step d).

One advantage thereof is that a strong field effect conducive to good passivation of the surfaces of the substrate is created, and that a good quality electrical contact zone is formed.

According to one feature of the invention, the process comprises a step e) of forming first and second transparent-conductive-oxide layers on the first and second polysilicon layers, respectively, step e) being executed after step d).

One advantage of the transparent-conductive-oxide layers is in particular to ensure electrical contact between an electrode (a metal electrode for example) and the substrate. The transparent-conductive-oxide layers may, with a suitable thickness, also act as an antireflection layer. The antireflection layer allows optical losses related to reflection of light radiation to be decreased, and therefore allows the absorption of light radiation by the substrate to be optimized.

According to one feature of the invention, the process comprises a step f) of forming electrodes on the first and second transparent-conductive-oxide layers.

### Definitions

By “passivation”, what is meant is neutralization of electrically active defects on the surfaces of the substrate. Specifically, a surface of a crystalline silicon substrate has a density of defects (e.g. dangling bonds, impurities, crystal discontinuity, etc.) that may lead to non-negligible losses related to surface recombination of carriers in the case of a photovoltaic application.
By “substrate”, what is meant is the self-supporting mechanical carrier intended for manufacturing a photovoltaic cell. The substrate may be a wafer cut from a crystalline silicon ingot.
By “crystalline”, what is meant is the multicrystalline or single-crystal form of silicon, therefore excluding amorphous silicon.
By “-based”, what is meant is that crystalline silicon is the main and predominant material of the substrate.
By “applied to the structure”, what is meant is that the ultraviolet radiation may be applied to all or part of the structure, i.e.:
either to a single side of the structure (the side defined by the first surface of the substrate), the side defined by the second surface of the substrate not being exposed to the ultraviolet radiation;
or successively to both sides of the structure.
By “thickness”, what is meant is the dimension extending normal to the first surface (or to the second surface) of the substrate.
By “composition”, what is meant is the atomic composition of an oxide film.
By “stoichiometric compound”, what is meant is a compound possessing an atomic composition having stoichiometric proportions. For example, when an oxide film is made of a silicon oxide SiO₂₋ₓ, silicon dioxide SiO₂ is a stoichiometric compound, possessing an atomic composition having stoichiometric proportions, whereas the silicon oxide SiO₂₋ₓ is a non-stoichiometric compound, possessing an atomic composition having non-stoichiometric proportions, “x” being the deviation from stoichiometry with x>0 or x<0.
By “closer”, what is meant is that the atomic proportions of the oxide film obtained at the end of step b) are closer to the stoichiometric proportions of the stoichiometric compound than the initial atomic proportions of the oxide film provided in step a). The atomic proportions of the oxide film obtained at the end of step b) may tend toward the stoichiometric proportions of the stoichiometric compound.
By “tending toward” or “tend toward”, what is meant is that the atomic proportions of the oxide film obtained at the end of step b) are sufficiently close to the stoichiometric proportions of the stoichiometric compound (i.e. decrease in the absolute value of the deviation “x” from stoichiometry) that the oxide film may be considered to behave as a stoichiometric oxide film.
The term “polysilicon” also designates polycrystalline silicon.
By “tunnel-oxide film”, what is meant is an oxide film that is sufficiently thin to advantageously permit an electric current to flow therethrough via a tunneling effect.
By “transparent-conductive-oxide” (TCO) what is meant is an oxide that is transparent in all or some of the solar spectrum and electrically conductive. For example, the transparent-conductive-oxide may have a transmittance greater than or equal to 60% (and preferably greater than or equal to 80%) over the spectrum [300 nm, 900 nm].
By “electrical activation”, what is meant is delivering energy of a thermal nature so as to cause migration of the dopants (phosphorus/boron atoms) to substitutional sites in which they will be likely to generate carriers.
Values X and Y expressed using the expression “between X and Y” or “comprised between X and Y” are included in the defined range of values.

### BRIEF DESCRIPTION OF THE DRAWINGS

Other features and advantages will become apparent from the detailed description of various embodiments of the invention, the description being accompanied by examples and references to the appended drawings.

FIGS. 1a to 1g (FIG. 1) are schematic cross-sectional views illustrating steps of a first implementation of a process according to the invention.

FIGS. 2a to 2g (FIG. 2) are schematic cross-sectional views illustrating steps of a second implementation of a process according to the invention.

FIGS. 3a to 3f (FIG. 3) are schematic cross-sectional views illustrating steps of a third implementation of a process according to the invention.

FIGS. 4a to 4f (FIG. 4) are schematic cross-sectional views illustrating steps of a fourth implementation of a process according to the invention.

FIGS. 5a to 5f (FIG. 5) are schematic cross-sectional views illustrating steps of a fifth implementation of a process according to the invention.

It should be noted that the drawings described above are schematic, and have not necessarily been drawn to scale for the sake of legibility and to simplify comprehension thereof. The cross sections have been cut normal to the first surface (or to the second surface) of the substrate.

### DETAILED DESCRIPTION OF THE EMBODIMENTS

For the sake of simplicity, elements that are identical or that perform the same function will have the same references in the various embodiments. Before step b), the first and second oxide films will be designated by the references “2” and “3”, respectively. The first and second oxide films will have the references “2” and “3”, respectively, if the corresponding oxide film has been modified or created by a UV-ozone treatment at the end of step b).

### UV-Ozone Treatment Modifying Existing Oxide Films

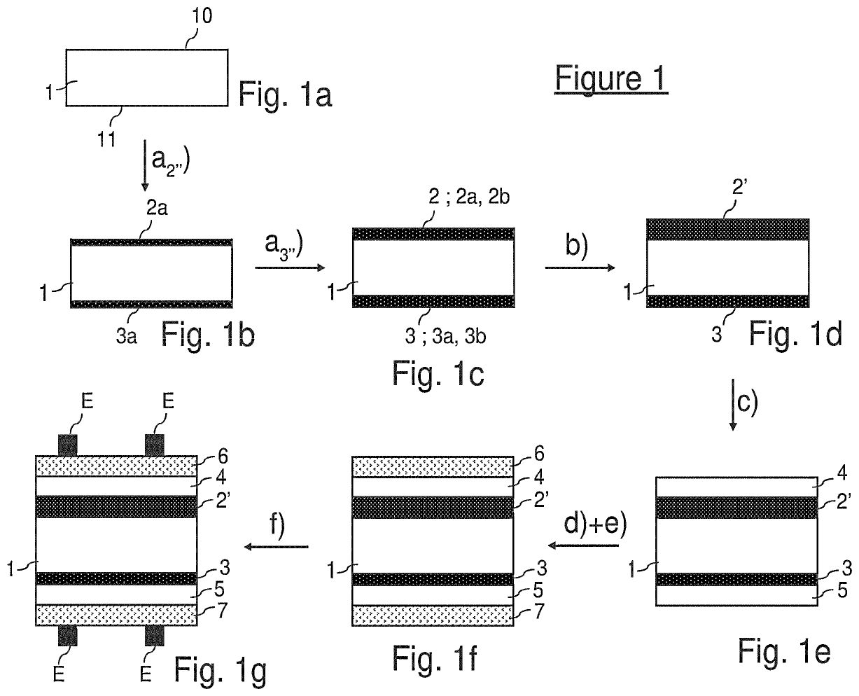

As illustrated in FIGS. 1 to 4, one subject of the invention is a passivation process, comprising the following successive steps:
a) providing a structure comprising:
   a crystalline silicon-based substrate 1 having opposite first and second surfaces 10, 11;
   first and second oxide films 2, 3 formed on the first and second surfaces 10, 11 of the substrate 1, respectively;
the situation at the end of step a) is illustrated in FIGS. 1c, 2b, 3b and 4b;
b) applying ultraviolet radiation to the structure, under an ozone atmosphere, in such a way that the first oxide film 2′ has:
   a thickness strictly greater than the thickness of the second oxide film 3, 3′; and/or
   a composition closer to the stoichiometric compound;
the situation at the end of step b) is illustrated in FIGS. 1d, 2d, 3c and 4c;
c) forming first and second polysilicon layers 4, 5 on the first and second oxide films 2′, 3; 2′, 3′, respectively, these first and second polysilicon layers comprising phosphorus atoms and boron atoms, respectively, the phosphorus atoms and boron atoms having first and second electrical activation temperatures, respectively, the second electrical activation temperature being strictly greater than the first electrical activation temperature; the situation at the end of step c) is illustrated in FIGS. 1e, 2e, 3d, 4d and 5d;
d) applying a heat treatment to the assembly comprising the structure and the first and second polysilicon layers 4, 5, the heat treatment being applied at a temperature greater than or equal to the second electrical activation temperature so as to electrically activate the phosphorus atoms and the boron atoms concomitantly.

### Step a)

The substrate 1 of the structure provided in step a) is advantageously doped n-type. The first and second surfaces 10, 11 of the substrate 1 may be intended to be exposed to light radiation so as to form a bifacial architecture.

Step a) is advantageously executed in such a way that the first and second surfaces 10, 11 of the substrate 1 are textured in order to reduce the reflection coefficient and optical losses in the photovoltaic cell. The first and second surfaces 10, 11 of the substrate 1 preferably comprise inverted pyramid features, arranged to create a surface roughness. The texturing is preferably executed by chemical etching based on potassium hydroxide KOH.

By way of non-limiting example, the substrate 1 may have a thickness of the order of 150 μm.

Step a) is advantageously executed in such a way that the first and second oxide films 2, 3 are of tunnel-oxide type. Step a) is advantageously executed in such a way that the first and second tunnel-oxide films 2, 3 have a thickness less than or equal to 3 nm, and preferably less than or equal to 2 nm.

The first and second oxide films 2, 3 are advantageously silicon oxides. By “silicon oxide”, what is meant is a compound of formula SiO₂₋ₓ.

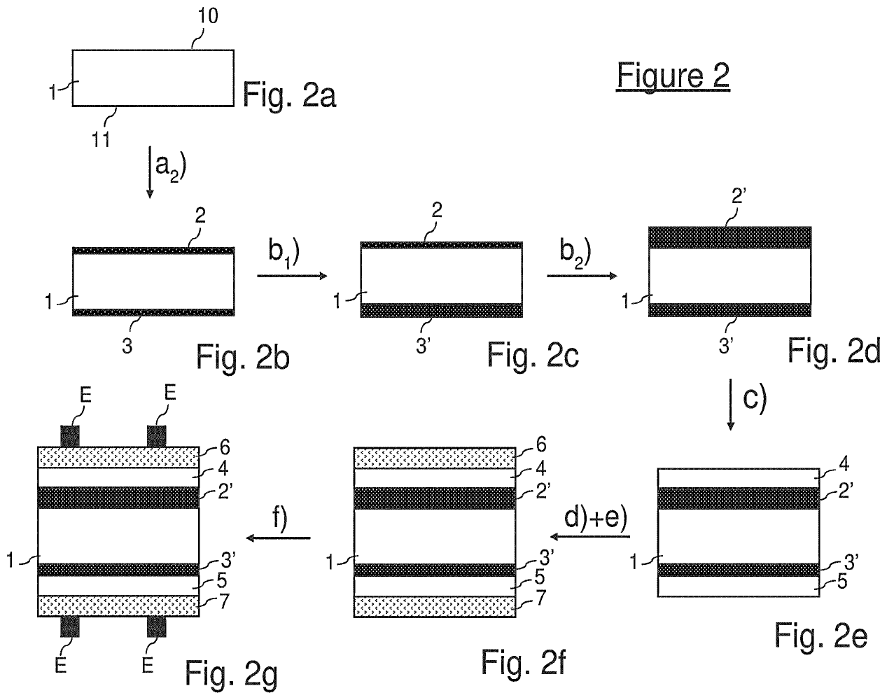

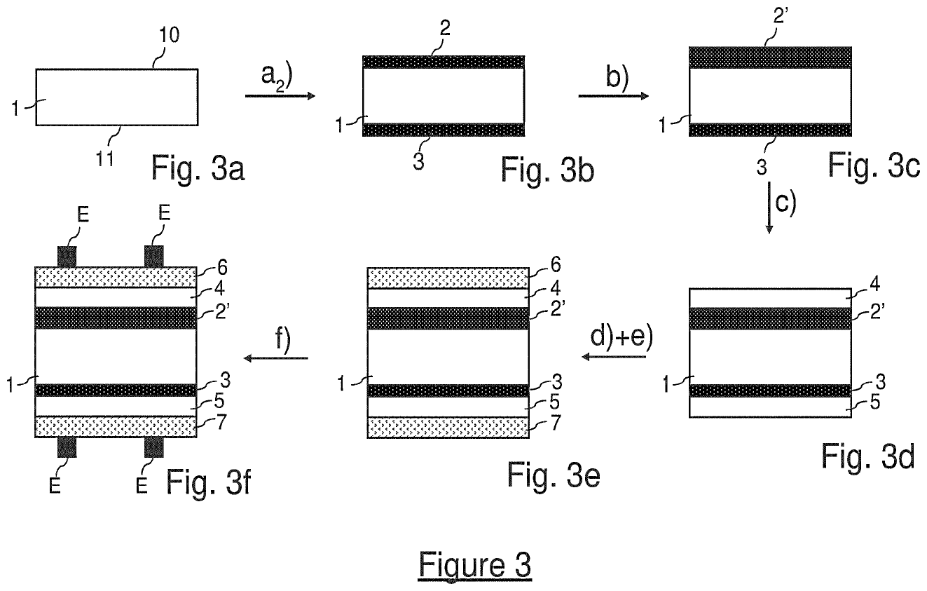

According to one implementation illustrated in FIGS. 2 and 3, step a) comprises the following steps:
a₁) providing a crystalline silicon-based substrate 1 having opposite first and second surfaces 10, 11; step a₁) is illustrated in FIGS. 2a and 3a;
a₂) chemically treating the first and second surfaces 10, 11 of the substrate 1 with an oxidizing agent so as to form the first and second oxide films 2, 3; step a₂) is illustrated in FIGS. 2b and 3b.

Step a₂) may comprise the following steps:
a₂₀) applying a hydrofluoric (HF) acid solution to the first and second surfaces 10, 11 of the substrate 1 in order to deoxidize them;
a₂₁) rinsing the first and second surfaces 10, 11 of the substrate 1 with deionized water to reoxidize them.

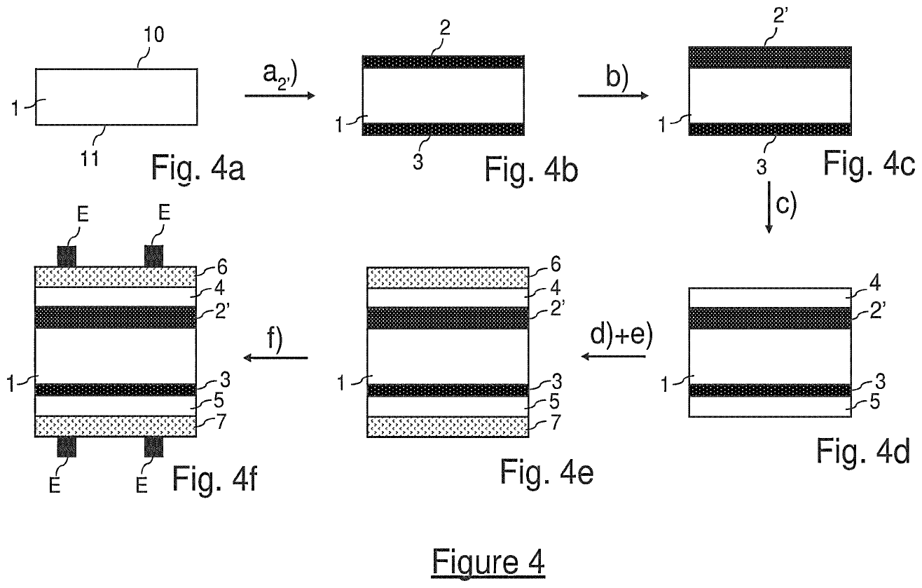

According to one implementation illustrated in FIG. 4, step a) comprises the following steps:
a_{1′}) providing a crystalline silicon-based substrate 1 having opposite first and second surfaces 10, 11; step a_{1′}) is illustrated in FIG. 4a;
a_{2′}) heat treating the first and second surfaces 10, 11 of the substrate 1 so as to form first and second films 2, 3 of thermal-oxide type; step a_{2′}) is illustrated in FIG. 4b.

By way of non-limiting example, step a_{2′}) may be executed at a temperature of 580° C.

According to one implementation illustrated in FIG. 1, step a) comprises the following steps:
a_{1″}) providing a crystalline silicon-based substrate 1 having opposite first and second surfaces 10, 11; step a_{1″}) is illustrated in FIG. 1a;
a_{2″}) chemically treating the first and second surfaces 10, 11 of the substrate 1 with an oxidizing agent so as to form a first portion 2a, 3a of the first and second oxide films 2, 3; step a_{2″}) is illustrated in FIG. 1b;
a_{3″}) heat treating the oxidized first and second surfaces 10, 11 of the substrate 1 so as to form a second portion 2b, 3b of the first and second oxide films 2, 3; step a_{3″}) is illustrated in FIG. 1c.

Step a_{2″}) may comprise the following steps:
a_{20″}) applying a hydrofluoric (HF) acid solution to the first and second surfaces 10, 11 of the substrate 1 in order to deoxidize them;
a_{21″}) rinsing the first and second surfaces 10, 11 of the substrate 1 with deionized water to reoxidize them.

By way of non-limiting example, step a_{3″}) may be executed at a temperature of 580° C.

### Step b)

According to one implementation illustrated in FIGS. 1, 3 and 4, step b) consists in applying ultraviolet radiation, under the ozone atmosphere, to only one side of the structure, in the present case the side defined by the first surface 10 of the substrate 1, i.e. the side on which phosphorus atoms will be present in step c). The first oxide film 2 obtained at the end of step b) has been referenced “2”. The ultraviolet radiation is applied under the ozone atmosphere, in such a way that the first oxide film 2′ has, at the end of step b):
a thickness strictly greater than the thickness of the second oxide film 3; and/or
a composition closer to the stoichiometric compound.

According to one implementation illustrated in FIG. 2, step b) comprises the following steps:
b₁) applying first ultraviolet radiation, under the ozone atmosphere, to the side of the structure defined by the second surface 11 of the substrate 1, so as to increase the thickness and/or modify the composition of the second oxide film 3; step b₁) is illustrated in FIG. 2c; the second oxide film 3 obtained at the end of step b₁) has been referenced “3”
b₂) applying second ultraviolet radiation, under the ozone atmosphere, to the side of the structure defined by the first surface 10 of the substrate 1, so as to increase the thickness and/or modify the composition of the first oxide film 2; step b₂) is illustrated in FIG. 2d; the first oxide film 2 obtained at the end of step b₁) has been referenced “2”′.

The ultraviolet radiation is applied in step b₂), under the ozone atmosphere, in such a way that the first oxide film 2′ has, at the end of step b₂):
a thickness strictly greater than the thickness of the second oxide film 3′ [i.e. second oxide film obtained at the end of step b₁)]; and/or
a composition closer to the stoichiometric compound.

To this end, those skilled in the art may in particular increase the duration of exposure to ultraviolet radiation in step b₂) compared with step b₁), for ultraviolet radiation of given power density per unit area.

Steps b₁) and b₂) are not concomitant but successive. It should be noted that the order of steps b₁) and b₂) may be inverted.

### UV-Ozone Treatment Creating Oxide Films

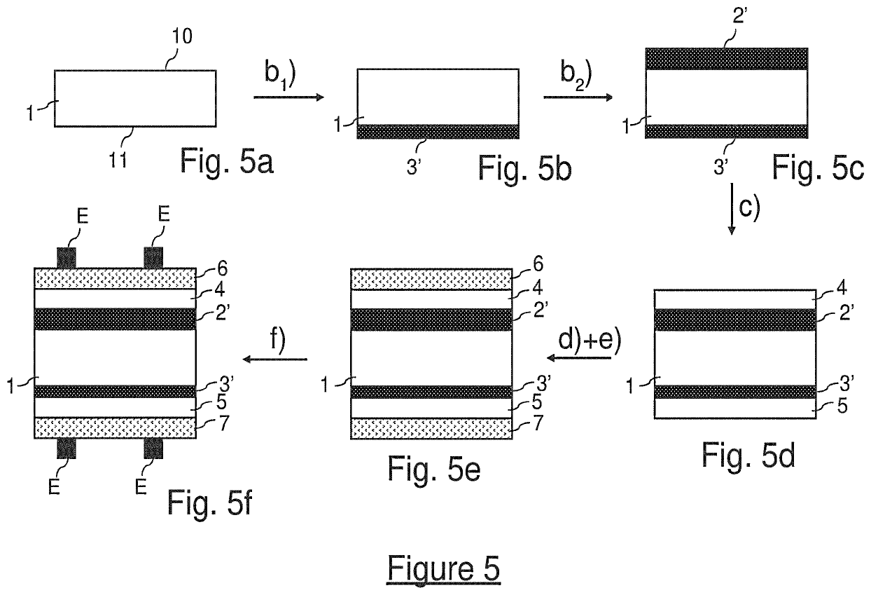

As illustrated in FIG. 5, one subject of the invention is a passivation process, comprising the following successive steps:
a′) providing a crystalline silicon-based substrate 1 having opposite first and second surfaces 10, 11; step a′) is illustrated in FIG. 5a;
b) applying ultraviolet radiation to the substrate 1, under an ozone atmosphere, so as to form first and second oxide films 2′, 3′ on the first and second surfaces 10, 11 of the substrate 1, respectively, the first oxide film 2′ having:
   a thickness strictly greater than the thickness of the second oxide film 3′, and/or
   a composition tending toward the stoichiometric compound;
step b) is illustrated in FIGS. 5b and 5c;
c) forming first and second polysilicon layers 4, 5 on the first and second oxide films 2′, 3′, respectively, these first and second polysilicon layers comprising phosphorus atoms and boron atoms, respectively, the phosphorus atoms and boron atoms having first and second electrical activation temperatures, respectively, the second electrical activation temperature being strictly greater than the first electrical activation temperature; the situation at the end of step c) is illustrated in FIG. 5d;
d) applying a heat treatment to the assembly comprising the substrate 1, the first and second oxide films 2′, 3′ and the first and second polysilicon layers 4, 5, the heat treatment being applied at a temperature greater than or equal to the second electrical activation temperature so as to electrically activate the phosphorus atoms and the boron atoms concomitantly.
   Step a′)

The substrate 1 provided in step a′) is advantageously doped n-type. The first and second surfaces 10, 11 of the substrate 1 may be intended to be exposed to light radiation so as to form a bifacial architecture.

Step a′) is advantageously executed in such a way that the first and second surfaces 10, 11 of the substrate 1 are textured in order to reduce the reflection coefficient and optical losses in the photovoltaic cell. The first and second surfaces 10, 11 of the substrate 1 preferably comprise inverted pyramid features, arranged to create a surface roughness. The texturing is preferably executed by chemical etching based on potassium hydroxide KOH.

By way of non-limiting example, the substrate 1 may have a thickness of the order of 150 μm.

### Step b)

Step b) is advantageously executed in such a way that the first and second oxide films 2′, 3′ are of tunnel-oxide type. Step b) is advantageously executed in such a way that the first and second tunnel-oxide films 2′, 3′ have a thickness less than or equal to 3 nm, and preferably less than or equal to 2 nm.

The first and second oxide films 2′, 3′ are advantageously silicon oxides. By “silicon oxide”, what is meant is a compound of formula SiO₂₋ₓ.

Step b) may comprise the following steps:
b₁) applying first ultraviolet radiation, under the ozone atmosphere, to the side of the second surface 11 of the substrate 1, so as to form the second oxide film 3′; step b₁) is illustrated in FIG. 5b;
b₂) applying second ultraviolet radiation, under the ozone atmosphere, to the side of the first surface 10 of the substrate 1, so as to form the first oxide film 2′; step b₂) is illustrated in FIG. 5c.

The ultraviolet radiation is applied in step b₂), under the ozone atmosphere, in such a way that the first oxide film 2′ has, at the end of step b₂):
a thickness strictly greater than the thickness of the second oxide film 3′; and/or
a composition tending toward the stoichiometric compound.

To this end, those skilled in the art may in particular increase the duration of exposure to ultraviolet radiation in step b₂) compared with step b₁), for ultraviolet radiation of given power density per unit area.

Steps b₁) and b₂) are not concomitant but successive. It should be noted that the order of steps b₁) and b₂) may be inverted.

### Features Common to the Subjects of the Invention

### Step b)

The ultraviolet radiation applied in step b), under the ozone atmosphere, is advantageously configured so that the thickness and/or composition of the first oxide film 2′ at the end of step b) limit/limits diffusion of phosphorus atoms into the substrate in step d).

The ultraviolet radiation is advantageously applied in step b), under the ozone atmosphere, with a power density per unit area comprised between 28 W/cm² and 32 W/cm².

The ultraviolet radiation is advantageously applied in step b), under the ozone atmosphere, with a wavelength in the absorption band of ozone, preferably comprised between 250 nm and 255 nm.

### Step c)

Step c) advantageously comprises the following steps:
c₁) forming the first and second polysilicon layers 4, 5 on the first and second oxide films 2′, 3; 2′, 3′, respectively;
c₂) implanting phosphorus atoms and boron atoms in the first and second polysilicon layers 4, 5, respectively, preferably by plasma-immersion ion implantation.

It is then a question of ex-situ doping of the first and second polysilicon layers 4, 5, with phosphorus atoms and boron atoms, respectively.

When step c₂) is executed by plasma-immersion ion implantation, the implantation of the phosphorus atoms is preferably carried out under an atmosphere containing phosphine PH₃, whereas the implantation of the boron atoms is preferably carried out under an atmosphere containing diborane B₂H₆.

Step c) is advantageously executed in such a way that the phosphorus atoms and boron atoms, implanted in the first and second polysilicon layers 4, 5, respectively, have a density greater than 10²⁰ at./cm³ at the end of step d), i.e. after electrical activation.

Step c) is advantageously executed so that the first and second polysilicon layers 4, 5 have a thickness comprised between 10 nm and 200 nm, preferably comprised between 10 nm and 15 nm.

It should be noted that the doping of the first and second polysilicon layers 4, 5, with phosphorus atoms and boron atoms, respectively, may be in-situ doping. Step c) may be executed by depositing first and second layers of amorphous silicon, on the first and second oxide films 2′, 3; 3′, respectively, for example by low-pressure chemical vapor deposition (LPCVD) or plasma-enhanced chemical vapor deposition (PECVD). Then the phosphorus atoms and boron atoms may be implanted in the first and second amorphous-silicon layers, respectively, for example by plasma-immersion ion implantation. The heat treatment of step d) is configured to crystallize the first and second amorphous-silicon layers so as to obtain first and second polysilicon layers 4, 5.

### Step d)

The heat treatment applied in step d) is advantageously a thermal anneal. By “thermal anneal”, what is meant is a heat treatment comprising:
a phase of gradual increase in temperature (ramp up) until a temperature known as the annealing temperature is reached,
a phase in which the annealing temperature is maintained (plateau), for a period called the annealing time,
a cooling phase.

The temperature (annealing temperature) at which the heat treatment is applied in step d) is advantageously comprised between 950° C. and 1050° C. By way of non-limiting example, the annealing time may be of the order of 30 minutes.

The thermal anneal applied in step d) is a blanket thermal anneal in the sense that it is applied to the assembly comprising the substrate 1, the first and second oxide films 2, 3; 3′ and the first and second polysilicon layers 4, 5. It is therefore not a localized thermal anneal applied to one portion of said assembly, for example using a laser.

Step d) is preferably executed in an oven. Step d) may be executed under an oxidizing atmosphere or under a neutral atmosphere. The oxidizing atmosphere may contain a mixture of dioxygen and of a neutral gas chosen from argon and nitrogen.

### Step e)

As illustrated in FIGS. 1f, 2f, 3e, 4e and 5e, the process advantageously comprises a step e) of forming first and second transparent-conductive-oxide layers 6, 7 on the first and second polysilicon layers 4, 5, respectively, step e) being executed after step d).

The first and second transparent-conductive-oxide layers 6, 7 are advantageously made of a material chosen from CuO, NiO, TiO, a tin-doped fluorine oxide, indium-tin oxide, tin oxide (SnO₂), and zinc oxide (ZnO); the SnO₂ and ZnO are preferably doped with fluorine and aluminum, respectively.

### Step f)

As illustrated in FIGS. 1g, 2g, 3f, 4f and 5f, the process advantageously comprises a step f) of forming electrodes E on the first and second transparent-conductive-oxide layers 6, 7. More precisely, step f) may consist in forming at least one electrode E on the first transparent-conductive-oxide layer 6, and at least one electrode E on the second transparent-conductive-oxide layer 7. Step f) advantageously comprises a metallization step, which is preferably executed by screen printing. Each electrode E is preferably made of silver and/or aluminum.

The invention is not limited to the described embodiments. Those skilled in the art will be able to consider technically workable combinations thereof, and to substitute equivalents therefor.

1. A passivation process, comprising the following successive steps:
a) providing a structure comprising:
a crystalline silicon-based substrate having opposite first and second surfaces;
first and second oxide films formed on the first and second surfaces of the substrate, respectively;
b) applying ultraviolet radiation to the structure, under an ozone atmosphere, in such a way that the first oxide film has:
a thickness strictly greater than the thickness of the second oxide film, and/or
a composition closer to the stoichiometric compound;
c) forming first and second polysilicon layers on the first and second oxide films, respectively, these first and second polysilicon layers comprising phosphorus atoms and boron atoms, respectively, the phosphorus atoms and boron atoms having first and second electrical activation temperatures, respectively, the second electrical activation temperature being strictly greater than the first electrical activation temperature;
d) applying a heat treatment to the assembly comprising the structure and the first and second polysilicon layers, the heat treatment being applied at a temperature greater than or equal to the second electrical activation temperature so as to electrically activate the phosphorus atoms and the boron atoms concomitantly.

2. The process as claimed in claim 1, wherein step a) comprises the following steps:
a₁) providing a crystalline silicon-based substrate having opposite first and second surfaces;
a₂) chemically treating the first and second surfaces of the substrate with an oxidizing agent so as to form the first and second oxide films.

3. The process as claimed in claim 1, wherein step a) comprises the following steps:
a_{1′}) providing a crystalline silicon-based substrate having opposite first and second surfaces;
a_{2′}) heat treating the first and second surfaces of the substrate so as to form first and second films of thermal-oxide type.

4. The process as claimed in claim 1, wherein step a) comprises the following steps:
a_{1″}) providing a crystalline silicon-based substrate having opposite first and second surfaces;
a_{2″}) chemically treating the first and second surfaces of the substrate with an oxidizing agent so as to form a first portion of the first and second oxide films;
a_{3″}) heat treating the oxidized first and second surfaces of the substrate so as to form a second portion of the first and second oxide films.

5. The process as claimed in claim 1, wherein step a) is executed in such a way that the first and second oxide films are of tunnel-oxide type.

6. A passivation process, comprising the following successive steps:
a′) providing a crystalline silicon-based substrate having opposite first and second surfaces;
b) applying ultraviolet radiation to the substrate, under an ozone atmosphere, so as to form first and second oxide films on the first and second surfaces of the substrate, respectively, the first oxide film having:
a thickness strictly greater than the thickness of the second oxide film, and/or
a composition tending toward the stoichiometric compound;
c) forming first and second polysilicon layers on the first and second oxide films, respectively, these first and second polysilicon layers comprising phosphorus atoms and boron atoms, respectively, the phosphorus atoms and boron atoms having first and second electrical activation temperatures, respectively, the second electrical activation temperature being strictly greater than the first electrical activation temperature:
d) applying a heat treatment to the assembly comprising the substrate, the first and second oxide films and the first and second polysilicon layers, the heat treatment being applied at a temperature greater than or equal to the second electrical activation temperature so as to electrically activate the phosphorus atoms and the boron atoms concomitantly.

7. The process as claimed in claim 6, wherein step b) is executed in such a way that the first and second oxide films are of tunnel-oxide type.

8. The process as claimed in claim 1, wherein the ultraviolet radiation applied in step b), under the ozone atmosphere, is configured so that the thickness and/or composition of the first oxide film at the end of step b) limit/limits diffusion of phosphorus atoms into the substrate in step d).

9. The process as claimed in claim 1, wherein the ultraviolet radiation is applied in step b), under the ozone atmosphere, with a power density per unit area comprised between 28 W/cm² and 32 W/cm².

10. The process as claimed in claim 1, wherein the ultraviolet radiation is applied in step b), under the ozone atmosphere, with a wavelength in the absorption band of ozone, preferably comprised between 250 nm and 255 nm.

11. The process as claimed in claim 1, wherein the temperature at which the heat treatment is applied in step d) is comprised between 950° C. and 1050° C.

12. The process as claimed in claim 1, wherein step c) comprises the following steps:
c₁) forming the first and second polysilicon layers on the first and second oxide films, respectively;
c₂) implanting phosphorus atoms and boron atoms in the first and second polysilicon layers, respectively, preferably by plasma-immersion ion implantation.

13. The process as claimed in claim 1, wherein step c) is executed in such a way that the phosphorus atoms and boron atoms have a density greater than 10²⁰ at./cm³ at the end of step d).

14. The process as claimed in claim 1, comprising a step e) of forming first and second transparent-conductive-oxide layers on the first and second polysilicon layers, respectively, step e) being executed after step d).

15. The process as claimed in claim 14, comprising a step f) of forming electrodes (E) on the first and second transparent-conductive-oxide layers.
